(19) United States
(12) Patent Application Publication
(10) Pub. No.: US 2007/0120467 A1
(43) Pub. Date: May 31, 2007

(54) Full-color organic electroluminescence display and its manufacturing method

(76) Inventors: Chien-Yuan Feng, Chu Nan (TW); Ting-Chou Chen, Chu Nan (TW); Chih-Ming Chin, Chu Nan (TW); Wen-Jang Lan, Chu Nan (TW); Chien-Chih Chiang, Chu Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/472,339

(22) Filed: Jun. 22, 2006

(30) Foreign Application Priority Data
Nov. 28, 2005 (TW) 94141762

(51) Int. Cl. H01J 1/62

(52) U.S. Cl. 313/504

(57) ABSTRACT

A full-color organic electroluminescence display has pixel units. Each pixel unit has a first electrode disposed on a transparent substrate. A first sub-pixel region, a second sub-pixel region, and a third sub-pixel region are defined on the first electrode. A first organic light-emitting layer is disposed over the first sub-pixel region; a second organic light-emitting layer is disposed on the second sub-pixel region; a third organic light-emitting layer is disposed on the third sub-pixel region and overlaying the first and second organic light-emitting layers. Each of the organic light-emitting layers emits light with a specific wavelength. A second electrode is disposed over the third organic light-emitting layer. A method for manufacturing the full-color organic electroluminescence display provides two mask procedures to form two OLELs on the first and the second sub-pixel regions respectively. A wide open mask alignment procedure is introduced to form the third OLEL on all sub-pixel regions.

### RELATED APPLICATIONS

The present application is based on, and claims priority from, Taiwan Application Serial Number 94141762, filed Nov. 28, 2005, the disclosure of which is hereby incorporated by reference herein in its entirety.

### BACKGROUND OF THE INVENTION

1. Field of Invention

The invention relates to an organic electroluminescence display (OELD) and, in particular, to a full-color organic electroluminescence display and the method of making the same.

2. Related Art

Generally speaking, the OELD has the advantages of self-illuminating, light-weight, wide-angle, high contrast, low power consumption, and high response speed. The structure of an OELD includes an anode on the substrate, an organic light-emitting layer (OLEL) on the anode, and a cathode on the organic light-emitting layer. When a voltage is imposed between the anode and the cathode, electrons and holes are driven into the OLEL, making the OLEL generate electroluminescence (EL).

The prior art provides many method of making full-color OELD, such as U.S. Pat. No. 6,515,428 with the title “Pixel structure an organic light-emitting diode display device and its manufacturing method.” First, the OLEL emits white light. The white then passes through color filters of different colors, thereby obtaining red, green, and blue light to achieve full colors. However, the technology of using the white light to pass color filters renders a penetration rate of a single color lower than 25% and bad color saturation. Moreover, using the photolithography process to prepare these color filters usually requires complicated steps and consumes a lot of time.

Another conventional technology, as in U.S. Pat. No. 6,522,066 with the title “Pixel structure of an organic light-emitting diode display device and its fabrication method,” uses different color conversion medium (CCM) layers to convert the blue light emitted by the OLEL and obtain red, green, and blue light, thereby achieving full-color effects. However, using the photolithography process to prepare the CCM layers also involves complicated steps and long time.

“OELD with color filters or color conversion media” disclosed in Korea Pat. App. 2001-0000943 uses a different single mask to form OLELs of different colors. However, since the opening of the mask of each pixel is tens of micrometers, therefore the alignment precision of the mask and the substrate is required to be very high. This increases the difficulty in the manufacturing process. Moreover, the OLELs of different colors use the side by side coating technique, which increases the production cost and time.

To achieve full-color effects, using different color filters on the white light produced by the white-light OLEL reduces the usage efficiency of the light and has worse color saturation. On the other hand, using the technology of separate coating involves a more complicated process and higher production cost. The process requires a high alignment precision, inevitably increasing the difficulty in production. Therefore, it is necessary to improve the structure of the OELD and solve the problem in the alignment precision of the mask, thereby enhancing the penetration rate, color saturation, brightness, and yield of the OELD.

### SUMMARY OF THE INVENTION

An objective of the invention is to provide an OELD that has enhanced brightness, penetration rate, and color saturation, achieving full colors in the OELD. A lower driving voltage is required in practice. Therefore, it has a longer lifetime.

According to a preferred embodiment of the invention, the structure of the OELD includes a plurality of pixel units. Each pixel unit includes a first electrode, a first OLEL, a second OLEL, a third OLEL, and a second electrode. The first electrode is disposed over a transparent substrate and has a first sub-pixel electrode region, a second sub-pixel electrode region, and a third sub-pixel electrode region. The first OLEL is disposed on the first sub-pixel electrode region. The second OLEL is disposed on the second sub-pixel electrode region. The third OLEL is disposed on the third sub-pixel electrode region, overlaying the first OLEL and the second OLEL. The OLELs have different light-emitting spectra. The second electrode is disposed on the third OLEL.

Another objective of the invention is to provide a method of making an OELD. A wide open mask alignment procedure is introduced to increase the alignment error tolerance, thereby decreasing the difficulty in production while enhancing the yield.

According to a preferred embodiment of the invention, a first electrode is first formed on a transparent substrate. Afterwards, a first sub-pixel region, a second sub-pixel region, and a third sub-pixel region are defined on the first electrode. A first mask is used to cover the second sub-pixel region and the third sub-pixel region, and a first OLEL is formed on the first sub-pixel region. A second mask is used to cover the first sub-pixel region and the third sub-pixel region, and a second OLEL is formed on the second sub-pixel region. A third OLEL is formed on the third sub-pixel region, covering the first OLEL and the second OLEL. The OLELs have different light-emitting spectra. Finally, a second electrode is formed on the third OLEL. The light emitted by the first OLEL and the second OLEL can be any two of red, green, and blue light. The light emitted by the third OLEL can be the other color of the three or white light.

In summary, the disclosed OELD uses an open mask to replace the conventional mask in the step of coating the OLEL through vaporization. Color filters or CCM layers are selectively used for filtering or modifying light. The allowed error in the mask alignment is thus increased. This can reduce the difficulty in production and increase the yield.

If each color filter is provided with an OLEL with the corresponding color, the brightness and color saturation and penetration rate of the OELD can be enhanced. If the absorption spectrum of each CCM corresponds to the light-emitting spectrum of the OLEL thereon, the brightness and color saturation can be enhanced too. Therefore, the disclosed OELD has a better light-emitting efficiency. It only needs a lower driving voltage, thus reducing its power consumption and elongating its lifetime. The invention thus achieves full colors of the OELD for applications in larger displays.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 shows a cross-sectional view of the OELD in accord with a preferred embodiment of the invention;

FIG. 2 is a cross-sectional view of the OELD in accord with another embodiment of the invention;

FIG. 3 is a cross-sectional view of the OELD with an alignment error in yet another embodiment;

FIG. 4 is a flowchart showing the manufacturing method of the disclosed OELD in accord with a preferred embodiment of the invention; and

FIG. 5 is a flowchart showing the manufacturing method of the disclosed OELD in accord with another embodiment of the invention.

### DETAILED DESCRIPTION OF THE INVENTION

The present invention will be apparent from the following detailed description, which proceeds with reference to the accompanying drawings, wherein the same references relate to the same elements.

The invention provides an OELD. After forming a first OLEL and a second OLEL, an open mask is used to form a third OLEL on the first OLEL and the second OLEL, thereby improving the mask alignment in the conventional process. Moreover, color filters or CCM layers of the corresponding colors can be used to filter or modify the colors. Therefore, even if the mask alignment exceeds the allowed error, the invention can still achieve full-color effects.

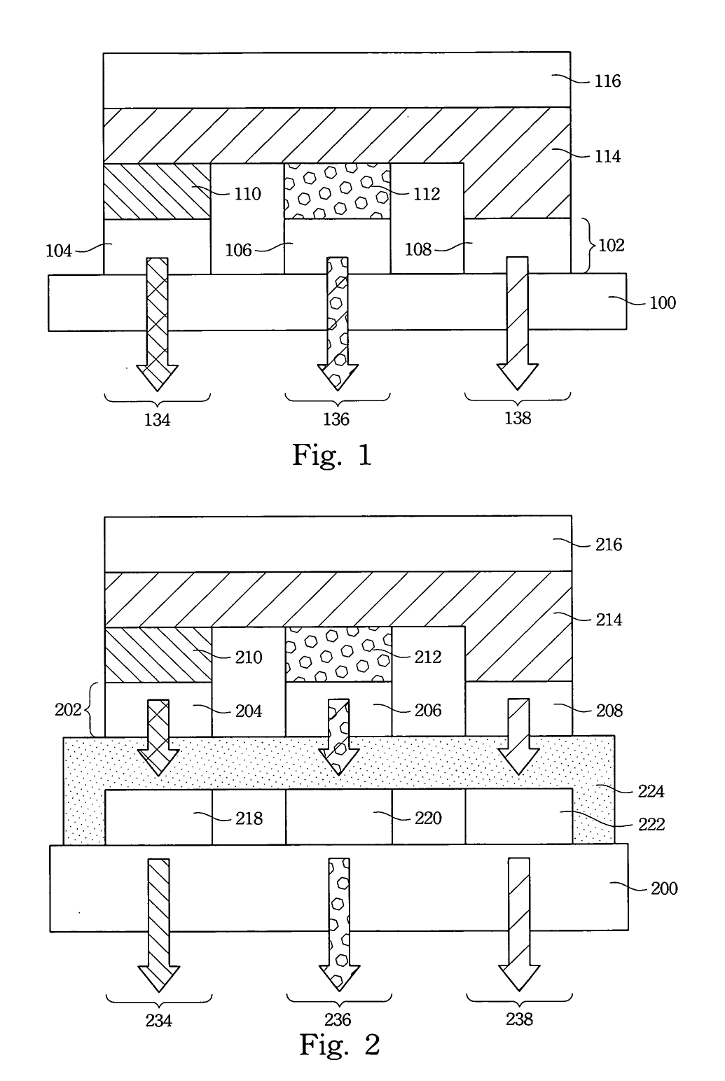

FIG. 1 shows a cross-sectional view of the OELD in accord a preferred embodiment of the invention. To clearly elucidate the preferred embodiment, a single pixel unit is used in the following drawings for the explanation. The pixel unit of the OELD includes transparent substrate 100, a first electrode 102, a first OLEL 110, a second OLEL 112, a third OLEL 114, and a second electrode 116.

The first electrode 102 is disposed on the transparent substrate 100. The first electrode 102 is defined with a first sub-pixel region 104, a second sub-pixel region 106, and a third sub-pixel region 108. The first OLEL 110 is formed on the first sub-pixel region 104. The second OLEL 112 is formed on the second sub-pixel region 106. The third OLEL 114 is formed on the third sub-pixel region 108 and covers the first OLEL 110 and the second OLEL 112. The OLELs 110, 112, 114 have different light-emitting spectra. The second electrode 116 is disposed on the third OLEL 114.

In this embodiment, the light-emitting spectra of the first OLEL 110, the second OLEL 112, and the third OLEL 114 are essentially the three primitive colors. For example, the light-emitting spectrum of the first OLEL 110 is red (R), with a wavelength in the range of 585-780 nm. The light-emitting spectrum of the second OLEL 112 is green (G), with a wavelength in the range of 485-585 nm. The light-emitting spectrum of the third OLEL 114 is blue (B), with a wavelength in the range of 380-485 nm.

In the above-mentioned structure, the light (e.g., blue) emitted by the third OLEL 114 on the top overlaps with the light (e.g., red, green) emitted by the first and second OLELs 110, 112 below it. However, experimental results show that the light emitted by the third OLEL 114 does not have much influence on the visual perception of the viewer. Therefore, using this structure, a desired color (e.g. red, green, and blue) can be obtained from the first color range 134, the second color range 136, and the third color range 138. That is, this preferred embodiment can use a simple structure to achieve the full-color effects of the OELD without the use of color filters.

As shown in FIG. 1, each of the three OLELs emits one of the three primitive colors, and experimental results indicate that full-color effects can be achieved without the use of color filters. Of course, the disclosed OELD can be provided with color filters or CCM layers to filter or convert the colors to other colors similar with the three primitive colors.

FIG. 2 shows the cross-sectional view of the OELD in accord with another preferred embodiment of the invention. The first color filter 218 is disposed between the first sub-pixel region 204 and the transparent substrate 200. The second color filter 220 is disposed between the second sub-pixel region 206 and the transparent substrate 200. The third color filter 222 is disposed between the third sub-pixel region 208 and the transparent substrate 200. The spectrum of each of the color filters 218, 220, 222 corresponds to the light-emitting spectrum of the OLEL 210, 212, 214 above it.

For example, suppose the first color region 234, the second color region 236, and third color region 238 are required to emit red, green, and blue light, respectively. The red spectrum of the first color filter 218 corresponds to the red light-emitting spectrum of the first OLEL 210 and filters the non-red spectrum emitted by the third OLEL 214 above the first color filter 218. The green spectrum of the second color filter 220 corresponds to the green light-emitting spectrum of the second OLEL 212 and filters the non-green spectrum emitted by the third OLEL 214 on the second OLEL 212.

However, only the third OLEL 214 is disposed above the third color filter 222 with the same spectrum. If the third OLEL 214 already emits an ideal spectrum (e.g., blue), then the third color filter 222 of the same blue can be selectively disposed below it. If the third OLEL 214 emits a white spectrum, then the third color filter 222 has to be used in order to produce blue light in the third color region 238. A person skilled in the art can select appropriate materials and tune the production parameters so that the light-emitting spectra of the OLELs 210, 212, 214 directly match with the required colors. Alternatively, a third color filter 222 with a specific spectrum can be used so that the color emitted by the third OLEL 214 is close to the desired one, further enhancing the color saturation of the OELD. Of course, the first color region 234, the second color region 236, and the third color region 238 are not limited to the above-mentioned case to emit R, G, and B light respectively. Each color region can be any one of the three primitive colors.

According to another embodiment of the invention, when the light-emitting spectrum of the third OLEL 214 is the one required by the third sub-pixel region 208, the third color filter 222 below the third OLEL 214 can be omitted. Only the first color filter 218 and the second color filter 220 are disposed below the first OLEL 210 and the second OLEL 212, respectively. It should be noted that this embodiment can still include the third color filter 222 to filter out any possibly non-primitive spectrum emitted by the third OLEL 214.

On the other hand, in yet another embodiment of the invention, each of the first OLEL 210 and the second OLEL 212 emit one of the three primitive colors, and the third OLEL 214 emits a spectrum containing the third primitive color, such as white or blue light. In this case, three color filters can be used to filter out the light-emitting spectra of the three primitive colors. More explicitly, the light-emitting spectra of the first OLEL 210 and the second OLEL 212 substantially contain two of the three primitive colors. The light-emitting spectrum of the third OLEL 214 is the white light. For example, the light-emitting spectrum of the first OLEL 210 is red, that of the second OLEL 212 is green, and that of the third OLEL 214 is white.

Therefore, this embodiment uses three color filters to filter out the non-primitive color spectra. For example, the red spectrum of the first color filter 218 is used to filter out non-red spectrum emitted by the third OLEL 214. The green spectrum of the second color filter 220 is used to filter out the non-green spectrum emitted by the third OLEL 214. The blue spectrum of the third color filter 222 is used to filter out the non-blue spectrum emitted by the third OLEL 214. Consequently, the three primitive colors can be obtained using this combination.

The color filters used in the above-mentioned embodiments can be partially or completely replaced by CCM layers in another embodiment of the invention. Suppose that in this embodiment the first color region 234, the second color region 236, and the third color region 238 are required to emit red, green, and blue light, respectively. The first color filter 218, the second color filter 220, and the third color filter 222 in FIG. 2 are replaced respectively by a first CCM layer, a second CCM layer, and a third CCM layer. In other words, the first CCM layer is disposed between the first sub-pixel region 204 and the transparent substrate 200. The second CCM layer is disposed between the second sub-pixel region 206 and the transparent substrate 200. The third CCM layer is disposed between the third sub-pixel region 208 and the transparent substrate 200.

The absorptive spectrum of each CCM layer corresponds to the light-emitting spectrum of the OLEL 210, 212, 214 above it. When the OLELs 210, 212, 214 emit non-primitive colors, the CCM layers can appropriately convert the spectra emitted by the OLELs 210, 212, 214, releasing ideal primitive colors. This can enhance the light-emitting efficiency and color saturation. The disclosed OELD thus achieves full-color effects.

As described above, each of the three color regions 234, 236, and 238 emits one of the three primitive colors. Two CCM layers can be disposed under the sub-pixel regions 204, 206, and a CCM layer may be disposed under the OLEL 214 of the sub-pixel region 208 too, modifying the non-primitive spectra emitted by the OLELs 210, 212, 214. Likewise, there is no need for the third CCM layer in the third color region 238 if the third OLEL 214 already emits an ideal blue spectrum. Alternatively, if the first OLEL 210 and the second OLEL 212 emit two of the three primitive colors and the third OLEL 214 emits a spectrum containing the third primitive color, then three CCM layers are required to filter out the emitted non-primitive spectra.

In the above-mentioned embodiment, a planarized barrier layer 224 is disposed between the first electrode 202 and the transparent substrate 200. In a preferred embodiment of the invention, the planarized barrier layer 224 can be a transparent layer made of acryl resins or dix. The regions of the first OLEL 210, the second OLEL 212, and the third OLEL 214 correspond respectively to the sizes of the first color region 234, the second color region 236, and the third color region 238.

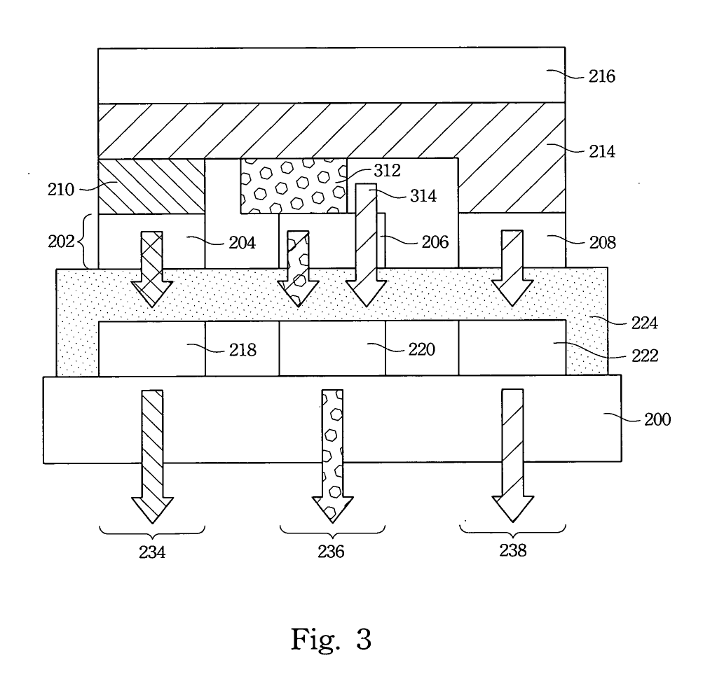

FIG. 3 is a cross-sectional view of the disclosed OELD in FIG. 2 with an alignment error. The same components in FIG. 3 use the same numeral references as in FIG. 2. With reference to FIG. 2, the vaporization of the organic light-emitting materials (not shown) in the OLELs 210, 212 requires the use of masks to avoid regions that do not need coating. Therefore, there is a mask alignment problem during the production. If there is an error in the mask alignment, the OLEL 312 may deviate from the second color region 236, as shown in FIG. 3. In this case, the light-emitting area of the second color region 236 is greatly reduced.

In this embodiment, the light-emitting area of the second color region 236 does not reduce much. When the light-emitting spectrum of the third OLEL 214 is white, the color 314 emitted by the third OLEL 214 can be used to compensate for the light-emitting area loss in the position-deviated second OLEL 312. The color 314 is filtered by the second color filter 220 and becomes the desired color in the second color region 236. Likewise, if the deviation occurs in the first OLEL 210 or the two OLELs 210, 212 below the third OLEL 214, the third OLEL 214 can compensate for the light-emitting area due to these deviations, increasing the light-emitting efficiency and color saturation.

In accord with the above description, the color filters can be replaced by CCM layers for converting the light-emitting spectra of the OLELs thereon into ideal primitive colors. When the wavelengths of the light-emitting spectrum of the third OLEL 214 are shorter (e.g., blue light), the colored light 314 emitted by the third OLEL 214 can be used to compensate for the light-emitting area loss in the position-deviated second OLEL 312. The second CCM layer converts it into light in the second color region 236. Likewise, if the deviation occurs in the first OLEL 210 or the two OLELs 210, 212 below the third OLEL 214, the third OLEL 214 can compensate the light-emitting area for these deviations, increasing the light-emitting efficiency and color saturation.

Therefore, if the second OLEL 312 has an alignment error in the production process, the light emitted by the third OLEL 214 is filtered or converted by the second color filter 220 or second CCM layer (not shown) into one of the three primitive colors. This then compensate for the light-emitting area loss due to the deviation in the second OLEL 312. Moreover, the second color filter 220 or second CCM layer can filter or convert the spectrum emitted by the third OLEL 214 into a more ideal primitive color. For the mask alignment precision problem, another embodiment of the invention provides an effective solution. Even if the mask alignment exceeds the desired precision, the invention can still implement the full-color OELD.

An embodiment is shown in FIG. 2. Each of the first and second OLELs 210, 212 has its own hole injection layer, hole transmission layer, and organic light-emitting material layer (not shown). The third OLEL 214 above the third sub-pixel region 208 has in sequence a hole injection layer, a hole transmission layer, an organic light-emitting material layer, an electron transmission layer, and an electron injection layer (not shown). Furthermore, the third OLEL 214 is above the first and second OLELs 210, 212, and includes in sequence an organic light-emitting material layer, an electron transmission layer, and an electron injection layer (not shown). The organic light-emitting material in the first, second, and third OLELs 210, 212, 214 can be a single light-emitting material or some a co-host/co-dopant material. When the OELD is in the form of bottom emission, the first electrode 202 is a transparent electrode. In this case, the material of the first electrode 202 can be ITO, IZO, IWO, or AZO. The material of the second electrode 216 can be any metal, alloy, or transparent conductive material. The transparent substrate 200 can be a glass substrate, a flexible substrate, a rigid substrate, or a plastic substrate. As illustrated in FIG. 1, a transparent substrate without any color filter can even be used for the disclosed OELD when no color filter is required.

In accord with the above embodiment, since each color filter corresponds to the spectrum of the OLEL above it, the penetration rate can optimally reach over 70%. Therefore, the invention has a good light usage rate. It improves the low penetration rate of smaller than 25% as white light penetrates through a color filter in the prior art. Besides, due to its good light usage rate, only a low driving voltage is required. This helps elongate the lifetime of the disclosed OELD.

Furthermore, using the color filters or CCM layers of the corresponding colors to filter or convert light can achieve better color saturation. This improves the full-color effects. Experimental results show that the color saturation can reach above 100%, largely improving the color saturation problem of white light with color filters in the prior art.

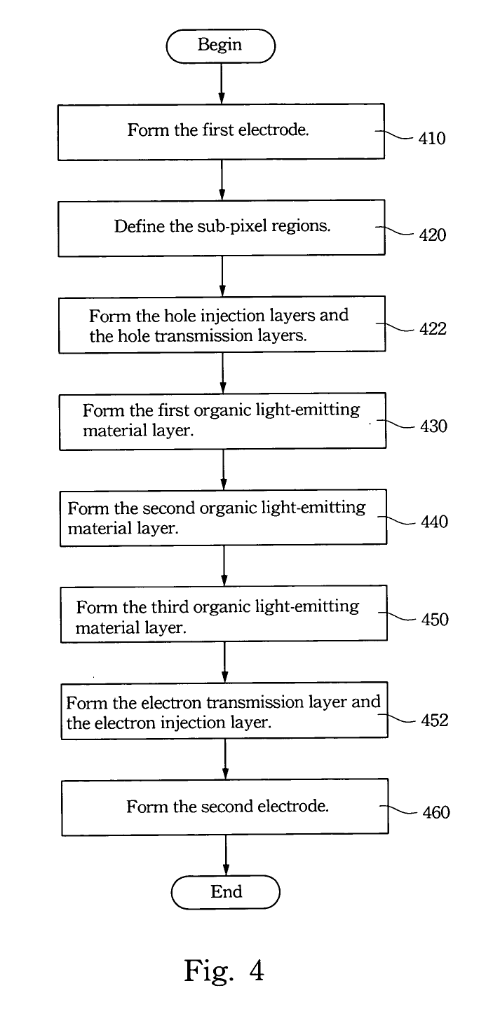

Please refer to FIG. 4 for the flowchart of the method of making the disclosed OELD according to a preferred embodiment of the invention. Please also refer to FIG. 1 simultaneously for the following explanation. In step 410, a first electrode 102 is formed on the transparent substrate 100. In step 420, a first sub-pixel region 104, a second sub-pixel region 106, and a third sub-pixel region 108 are defined on the first electrode 102. In step 422, the hole injection layers and the hole transmission layers (not shown in FIG. 1) of the first, second, and third OLELs 110, 112, 114 are formed respectively on the first, second, and third sub-pixel regions 104, 106, 108.

In step 430, a first mask is used to cover the second sub-pixel region 106 and the third sub-pixel region 108. A first organic light-emitting material layer of the first OLEL 110 is coated above the hole injection layer and the hole transmission layer of the first sub-pixel region 104. In step 440, a second mask is used to cover the first sub-pixel region 104 and the third sub-pixel region 108. A second organic light-emitting material layer of the second OLEL 112 is coated above the hole injection layer and the hole transmission layer of the second sub-pixel region 106. Afterwards, in step 450 an open mask is used to form a third organic light-emitting material layer of the third OLEL 114 on the hole injection layer and the hole transmission layer of the third sub-pixel region 108, also covering the organic light-emitting material layers of the first OLEL 110 and the second OLEL 112. The organic light-emitting material layers of the OLELs 110, 112, 114 emit different spectra. In step 452, the organic light-emitting layer of the third OLEL 114 is formed with an electron transmission layer and an electron injection layer (not shown in FIG. 1). In step 460, the second electrode 116 is formed on the electron transmission layer and the electron injection layer of the third OLEL 114.

More explicitly, the above embodiment employs an open mask to form the third OLEL 114, so that the third OLEL 114 covers the first OLEL 110 and the second OLEL 112. Therefore, it is possible to solve the mask alignment problem in the conventional evaporation process when forming the OLELs 110, 112, 114 that emit different colors of light. The tolerance in the mask alignment error becomes better, reducing difficulty in production.

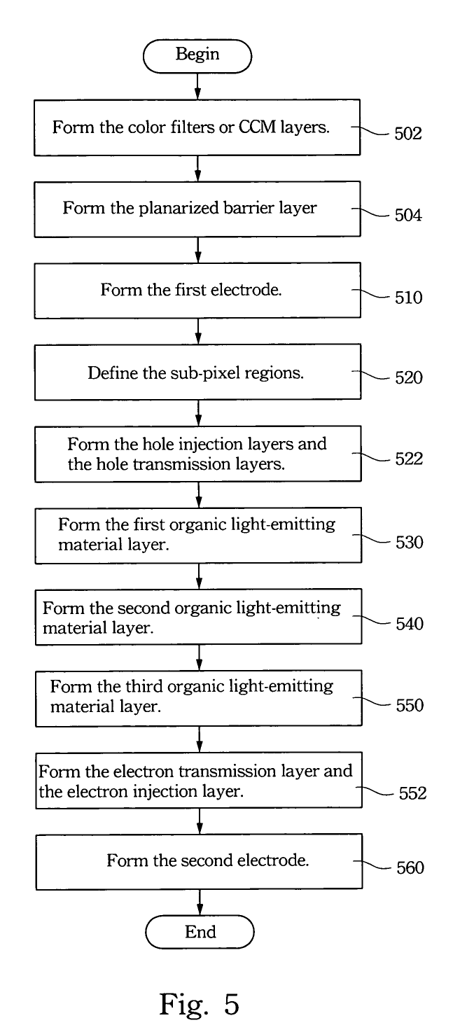

FIG. 5 gives the flowchart of another embodiment method of making the disclosed OELD. Please refer simultaneously to FIG. 2 in the following explanation. When each of the above-mentioned OLELs emits a primitive color, three or two color filters can be disposed to filter the spectra of the emitted light. In this embodiment, step 502 starts first to form a first color filter 218 and a second color filter 220. On the other hand, when the first OLEL 210 and the second OLEL 212 emit different primitive colors and the third OLEL 214 emits white light, three color filters 218, 220 and 222 can be used to filter and obtain the spectra of the three primitive colors.

More explicitly, the spectrum of each of the first OLEL 210 and the second OLEL 212 is essentially only one of the three primitive colors. Moreover, the spectrum of the third OLEL 214 is either white or contains the third primitive color. In this case, in addition to forming the first color filter 218 and the second color filter 220, a third color filter 222 is formed between the third sub-pixel region 208 and the transparent substrate 200, thereby filtering out the non-primitive spectrum emitted by the third OLEL 214. Therefore, this embodiment can render all the three primitive colors.

Each of the color filters in the above-mentioned embodiments can be replaced partially or completely by CCM layers in other embodiments. For example, a first CCM layer may be disposed between the first sub-pixel region 204 and the transparent substrate 200 (i.e., at the position of the above-mentioned first color filter 218). A second CCM layer may be disposed between the second sub-pixel region 206 and the transparent substrate 200 (i.e., at the position of the above-mentioned second color filter 220). Finally, a third CCM layer may be disposed between the third sub-pixel region 208 and the transparent substrate 200 (i.e., at the position of the above-mentioned third color filter 222).

Afterwards, step 504 is performed to planarized the color filters 218, 220, 222 or the CCM layers, forming a planarized barrier layer 224. The planarized barrier layer 224 can be a transparent layer and is preferably made of acrylic resins and dix.

In step 510, a first electrode 202 is formed above the planarized barrier layer 224. In step 520, a first sub-pixel region 204, a second sub-pixel region 206, and a third sub-pixel region 208 are defined on the first electrode 202. In step 522, the hole injection layers and hole transmission layers of the first, second, and third OLELs 210, 212, 214 are formed on the first, second, and third sub-pixel regions 204, 206, 208.

In step 530, a first mask is used to cover the second sub-pixel region 206 and the third sub-pixel region 208, forming the first organic light-emitting material layer of the first OLEL 210 on the hole injection layer and the hole transmission layer of the first sub-pixel region 204. In step 540, a second mask is used to cover the first sub-pixel region 204 and the third sub-pixel region 208, also forming the second organic light-emitting material layer of the second OLEL 212 on the hole injection layer and the hole transmission layer of the second sub-pixel region 206.

In step 550, an open mask is used to form the third organic light-emitting material layer of the third OLEL 214 on the hole injection layer and the hole transmission layer of the third sub-pixel region 208, covering the organic light-emitting layers of the first OLEL 210 and the second OLEL 212. The organic light-emitting material layers of the OLELs 210, 212, 214 have different spectra. In step 552, an electron transmission layer and an electron injection layer are formed on the organic light-emitting material layer of the third OLEL 214 (not shown in FIG. 2). In step 560, a second electrode 216 is formed on the electron transmission layer and the electron injection layer of the third OLEL 214. The above embodiment uses thermal evaporation to form the organic light-emitting material layers of the OLELs 210, 212, 214. The organic light-emitting material in the first, second, and third OLELs 210, 212, 214 can be a single light-emitting material or some a co-host/co-dopant material. When the OELD is in the form of bottom emission, the first electrode 202 is a transparent electrode. In this case, the material of the first electrode 202 can be ITO, IZO, IWO, or AZO. The material of the second electrode 216 can be any metal, alloy, or transparent conductive material. The transparent substrate 200 can be a glass substrate, a flexible substrate, a rigid substrate, or a plastic substrate.

In summary, the preferred embodiment of the invention uses an open mask to improve the conventional mask alignment problem during the manufacturing process of the OLELs with different colors. This solves the precision alignment problem of the mask and the substrate. The tolerance of the alignment error is better. Therefore, the invention can reduce the production difficulty and increase the yield.

Moreover, if an OLEL is disposed on each color filter of the corresponding color, then the penetration rate and color saturation of the colored light emitted by the OLELs can be increased. The color filters can be replaced by CCM layers. The light-emitting efficiency and color saturation of the disclosed OELD is enhanced by the color filters and/or CCM layers. Therefore, the disclosed OELD has a better light usage rate. In practice, only a low driving voltage is required. Therefore, the power consumption of the disclosed OELD can be reduced, while its lifetime is extended. The disclosed OELD also achieves full-color effects that may have applications in large displays.

The embodiments of the invention disclosed herein should not be used to limit other variations and applications of the invention. For example, the OELD can be used for both top emission and bottom emission. The invention can be applied to both passive and active OELDs. The color filters used herein can be in the form of color filters on transparent substrate, color filters on encap. glass, color filters on array (COA), or array on color filters (AOC). Likewise, the CCM layers disclosed herein can be in the form of CCM layers on transparent substrate, CCM layers on encap. glass, CCM layers on array, or array on CCM layers.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An organic electroluminescence display (OELD), comprising:
a plurality of pixel units on a transparent substrate, each of the pixel units includes:
a first electrode disposed on the transparent substrate and having a first sub-pixel region, a second sub-pixel region, and a third sub-pixel region;
a first organic light-emitting layer (OLEL) disposed on the first sub-pixel region;
a second OLEL disposed on the second sub-pixel region;
a third OLEL disposed on the third sub-pixel region and covering the first OLEL and the second OLEL, wherein the OLELs have different light-emitting spectra; and
a second electrode disposed on the third OLEL.

2. The OELD of claim 1, wherein the light-emitting spectrum of each of the first OLEL, the second OLEL, and the third OLEL is essentially one of the three primitive colors, respectively.

3. The OELD of claim 2, wherein the light-emitting spectra of the first OLEL, the second OLEL, and the third OLEL are essentially red, green, and blue spectra, respectively.

4. The OELD of claim 2 further comprising:
a first color filter disposed between the first sub-pixel region and the transparent substrate; and
a second color filter disposed between the second sub-pixel region and the transparent substrate;
wherein the spectrum of each of the color filters corresponds to the light-emitting spectrum of the OLEL above it.

5. The OELD of claim 1, wherein the first OLEL includes in sequence a first hole injection layer, a first hole transmission layer, and a first organic light-emitting material layer; the second OLEL includes in sequence a second hole injection layer, a second hole transmission layer, and a second organic light-emitting material layer on the second sub-pixel region; and the third OLEL include in sequence a third hole injection layer, a third hole transmission layer, and a third organic light-emitting material layer on the third sub-pixel region; the third organic light-emitting material layer covers the first organic light-emitting material layer and the second organic light-emitting material layer; an electron transmission layer is disposed on the third organic light-emitting material layer; and an electron injection layer is disposed on the electron transmission layer.

6. The OELD of claim 5, wherein the organic light-emitting material layers are made of a single light-emitting or a co-host/co-dopant.

7. The OELD of claim 1, wherein the spectra of the first OLEL and the second OLEL are essentially two of the three primitive colors and the spectrum of the third OLEL is white light.

8. The OELD of claim 7 further comprising:
a first color filter disposed between the first sub-pixel region and the transparent substrate;
a second color filter disposed between the second sub-pixel region and the transparent substrate; and
a third color filter disposed between the third sub-pixel region and the transparent substrate;
wherein the spectrum of each of the color filters corresponds to the light-emitting spectrum of the OLEL above it.

9. The OELD of claim 1 further comprising:
a first color conversion medium (CCM) layer disposed between the first sub-pixel region and the transparent substrate; and
a second CCM layer disposed between the second sub-pixel region and the transparent substrate;
wherein the light-emitting spectrum of each of the CCM layers is essentially one of the three primitive colors.

10. The OELD of claim 1 further comprising a third CCM layer disposed between the third sub-pixel region and the transparent substrate.

11. The OELD of claim 10, wherein each of the CCM layers has a spectrum corresponding to the light-emitting spectrum of the OLEL above it.

12. The OELD of claim 9 or 10, wherein the CCM layers are produced in the form of CCM layers on array or array on CCM layers.

13. The OELD of claim 1, wherein the first electrode is a transparent electrode.

14. The OELD of claim 13, wherein the transparent electrode is made of ITO, IZO, IWO, or AZO.

15. The OELD of claim 1, wherein the transparent substrate is a glass substrate, a flexible substrate, a rigid substrate, or a plastic substrate.

16. The OELD of claim 1, wherein the material of the second electrode is a metal, an alloy, or a transparent conductive material.

17. The OELD of claim 4, wherein the color filters are produced in the form of color filters on array (COA) or array on color filters (AOC).

18. The OELD of claim 8, wherein the color filters are produced in the form of color filters on array (COA) or array on color filters (AOC).

19. A manufacturing method of an OELD, comprising the steps of:
forming a first electrode on a transparent substrate;
defining a first sub-pixel region, a second sub-pixel region, and a third sub-pixel region on the first electrode;
using a first mask to cover the second sub-pixel region and the third sub-pixel region and forming a first OLEL on the first sub-pixel region;
using a second mask to cover the first sub-pixel region and the third sub-pixel region and forming a second OLEL on the second sub-pixel region;
forming a third OLEL on the third sub-pixel region and covering the first OLEL and the second OLEL, wherein the OLELs have different light-emitting spectra; and
forming a second electrode on the third OLEL.

20. The manufacturing method of claim 19 further comprising the step of using an open mask to form the third OLEL.

21. The manufacturing method of claim 19, wherein the light-emitting spectrum of each of the first OLEL, the second OLEL, and the third OLEL is essentially one of the three primitive colors, respectively.

22. The manufacturing method of claim 21, wherein the light-emitting spectra of the first OLEL, the second OLEL, and the third OLEL are essentially red, green, and blue spectra, respectively.

23. The manufacturing method of claim 21 further comprising the steps of:
forming a first color filter between the first sub-pixel region and the transparent substrate; and
forming a second color filter between the second sub-pixel region and the transparent substrate;
wherein the spectrum of each of the color filters corresponds to the light-emitting spectrum of the OLEL above it.

24. The manufacturing method of claim 19 further comprising the steps of:
forming a first hole injection layer, a second hole injection layer, and a third hole injection layer on the first sub-pixel region, the second sub-pixel region, and the third sub-pixel region, respectively,
forming a first hole transmission layer, a second hole transmission layer, and a third hole transmission layer on the first hole injection layer, the second hole injection layer, and the third hole injection layer, respectively;
forming a first organic light-emitting material layer on the first hole transmission layer;
forming a second organic light-emitting material layer on the second hole transmission layer;
forming a third organic light-emitting material layer on the third hole transmission layer, the first organic light-emitting material layer and the second organic light-emitting material layer;
forming an electron transmission layer on the third organic light-emitting material layer; and
forming an electron injection layer on the electron transmission layer.

25. The manufacturing method of claim 24, the organic light-emitting material layer is made of a single light-emitting or a co-host/co-dopant.

26. The manufacturing method of claim 19, wherein the OLELs are formed by thermal evaporation.

27. The manufacturing method of claim 19, wherein the light-emitting spectra of the first OLEL and the second OLEL essentially are two of the three primitive colors and the light-emitting spectrum of the third OLEL is white light.

28. The manufacturing method of claim 27 further comprising the steps of:
forming a first color filter between the first sub-pixel region and the transparent substrate;
forming a second color filter between the second sub-pixel region and the transparent substrate; and
forming a third color filter between the third sub-pixel region and the transparent substrate;
wherein the spectrum of each of the color filters corresponds to the light-emitting spectrum of the OLEL above it.

29. The manufacturing method of claim 19 further comprising the steps of:
forming a first CCM layer between the first sub-pixel region and the transparent substrate; and
forming a second CCM layer between the second sub-pixel region and the transparent substrate;
wherein the light-emitting spectrum of each of the CCM layers is essentially one of the three primitive colors, respectively.

30. The manufacturing method of claim 19 further comprising the step of forming a third CCM layer between the third sub-pixel region and the transparent substrate.

31. The manufacturing method of claim 30, wherein the absorption spectrum of each of the CCM layers corresponds to the light-emitting spectrum of the OLEL above it.

32. The manufacturing method of claim 29 further comprising the step of producing the CCM layers in the form of CCM layers on array or array on CCM layers.

33. The manufacturing method of claim 30 further comprising the step of producing the CCM layers in the form of CCM layers on array or array on CCM layers.

34. The manufacturing method of claim 19, wherein the first electrode is a transparent substrate.

35. The manufacturing method of claim 19, wherein the transparent substrate is a glass substrate, a flexible substrate, a rigid substrate, or a plastic substrate.

36. The manufacturing method of claim 19, wherein the second electrode is made of a metal, an alloy, or a transparent conductive material.

37. The manufacturing method of claim 23 further comprising the step of producing the color filters in the form of color filters on array (COA) or array on color filters (AOC).

38. The manufacturing method of claim 28 further comprising the step of producing the color filters in the form of color filters on array (COA) or array on color filters (AOC).
